(19) United States
(12) Patent Application Publication
(10) Pub. No.: US 2007/0145484 A1
(43) Pub. Date: Jun. 28, 2007

(54) Regulator circuit and semiconductor device therewith

(75) Inventors: Makoto Hosokawa, Tenri-Shi (JP); Toshihiko Fukushima, Nara-Shi (JP); Naoki Fukunaga, Soraku-Gun (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/591,479

(22) Filed: Nov. 2, 2006

(30) Foreign Application Priority Data
Dec. 22, 2005 (JP) 2005-369200

(51) Int. Cl. H01L 23/62

(52) U.S. Cl. 257/355

(57) ABSTRACT

A regulator circuit including an output-stage transistor for supplying a current to an external circuit has an electrostatic protection transistor formed in parallel with the output-stage transistor. The base of the electrostatic protection transistor is connected to, for example, the base of the output-stage transistor, or alternatively to a ground line or to the emitter of the electrostatic protection transistor itself.

This nonprovisional application claims priority under 35 U.S.C. § 119(a) on Patent Application No. 2005-369200 filed in Japan on Dec. 22, 2005, the entire contents of which are hereby incorporated by reference.

### BACKGROUND OF THE INVENTION

1. Field of the Invention

The present invention relates to a regulator circuit and to a semiconductor device incorporating it, and more particularly to a regulator circuit furnished with an electrostatic failure protection capability and to a semiconductor device incorporating such a regulator circuit. The present invention also relates to a fabrication method of such a semiconductor device.

2. Description of Related Art

FIG. 9 shows a circuit diagram of a conventional regulator system (regulator circuit) provided with an electrostatic failure protection element for protecting an output-stage transistor from electrostatic discharge (ESD). It is common practice that, as shown in FIG. 9, for the propose of preventing an output-stage transistor TR101 from breaking down by an inflow of transient charge attributable to static electricity via an input or output terminal, electrostatic protection transistors TR102 and TR103 are provided, one between the input terminal and ground and the other between the output terminal and ground, to act as electrostatic failure protection elements.

However, depending on the use of the product that incorporates the regulator system (i.e. depending on the circuit provided in the succeeding stage), the output potential (the potential at the output terminal) may become lower than the ground potential at start-up or the like. In this use, inconveniently, at the moment that the output potential becomes lower than the ground potential, the electrostatic protection transistor TR102 provided between the output terminal and ground operates in the forward direction to let a current flow, and thereby hampers correct operation of the circuit as a whole.

Hence, in a circuit so configured that the output potential may become lower than the ground potential, as shown in FIG. 10, usually no electrostatic protection transistor is provided on the output terminal side. Inconveniently, this makes the output-stage transistor prone to breakdown caused by an inflow of transient current via the output terminal, and thus diminishes the resistance of the circuit as a whole to static electricity.

One way to enhance the resistance to static electricity without the use of an electrostatic protection transistor is to secure sufficiently large spaces between the emitter diffusion region, base diffusion region, and collector diffusion region of the output-stage transistor and the element separation diffusion region. To be sure, this enhances the resistance to static electricity. However, since an output-stage transistor in a regulator system is supposed to let flow therethrough a current as large as several hundred milliamperes (mA) to several amperes (A), its size is already as large as several hundred micrometers (μm) to several millimeters (mm). Thus, securing the above-mentioned sufficiently large spaces further increases the size of the output-stage transistor.

Since an output-stage transistor occupies a very large proportion of the chip size in a semiconductor integrated circuit, making it larger leads to a larger chip size and hence a large increase in cost.

Incidentally, examples of conventional semiconductor devices provided with an electrostatic failure protection element are disclosed in JP-A-H4-369228 and JP-A-2003-007844.

As described above, with some conventional regulator systems, their use prohibits the provision of an electrostatic failure protection element on the output terminal side. Inconveniently, in such circuits, an output-stage transistor is prone to breakdown caused by an inflow of transient charge (static electricity) via the output terminal. Unfortunately, this inconvenience cannot be fully overcome with any of the technologies disclosed in the patent publications mentioned above.

### SUMMARY OF THE INVENTION

In view of the conventionally experienced inconveniences discussed above, it is an object of the present invention to provide a regulator circuit that offers enhanced resistance to static electricity and to provide a semiconductor device incorporating such a regulator circuit. It is another object of the present invention to provide a fabrication method of such a semiconductor device.

To achieve the above objects, according to one aspect of the present invention, in a regulator circuit including an output-stage transistor for supplying a current to an external circuit, an electrostatic protection transistor is formed in parallel with the output-stage transistor.

This structure promises enhanced resistance to static electricity.

Specifically, for example, the emitter, the base, and the collector of the electrostatic protection transistor may be connected respectively to the emitter, the base, and the collector of the output-stage transistor.

Or, for example, the emitter and the collector of the electrostatic protection transistor may be connected respectively to the emitter and the collector of the output-stage transistor, and the base of the electrostatic protection transistor may be connected to a reference potential point.

Or, for example, the emitter and the collector of the electrostatic protection transistor may be connected respectively to the emitter and the collector of the output-stage transistor, and the base and the emitter of the electrostatic protection transistor may be connected together.

To achieve the above objects, according to another aspect of the present invention, in a semiconductor device incorporating a regulator circuit including an output-stage transistor for supplying a current to an external circuit, the output-stage transistor and an electrostatic protection transistor are formed on a semiconductor substrate, and the electrostatic protection transistor is formed in parallel with the output-stage transistor.

Specifically, for example, the emitter area of the electrostatic protection transistor may be made smaller than the emitter area of the output-stage transistor.

More specifically, for example, the emitter area of the electrostatic protection transistor may be equal to or smaller than one-tenth of the emitter area of the output-stage transistor.

This structure helps suppress the influence of the electrostatic protection transistor on the output characteristics of the output-stage transistor.

Or, for example, the output-stage transistor and the electrostatic protection transistor may be formed on the semiconductor substrate while being separated by an element separation region, and the space between the base and the collector of the electrostatic protection transistor, the space between the emitter and the base of the electrostatic protection transistor, the space between the base of the electrostatic protection transistor and the part of the element separation region closest thereto, and the space between the collector of the electrostatic protection transistor and the part of the element separation region closest thereto may be made larger respectively than the comparable spaces in the output-stage transistor.

This structure promises enhanced resistance to transient charge in the electrostatic protection transistor, and hence promises enhanced resistance to transient charge in the circuit as a whole including the output-stage transistor.

Or, for example, the base impurity concentration of the electrostatic protection transistor may be made lower than the base impurity concentration of the output-stage transistor.

This structure allows the electrostatic protection transistor to operate faster, making it easier for transient charge to flow into it.

Or, for example, the emitter of the electrostatic protection transistor may be formed deeper than the emitter of the output-stage transistor.

This structure, too, allows the electrostatic protection transistor to operate faster, making it easier for transient charge to flow into it.

Or, for example, as seen from above the semiconductor substrate, the emitter, the base, and the collector of the electrostatic protection transistor may each be given an exterior shape including a curve.

This structure makes concentration of an electric field less likely, and thereby promises enhanced resistance to transient charge in the electrostatic protection transistor.

More specifically, for example, the exterior shape of each of the emitter, the base, and the collector of the electrostatic protection transistor may be made circular.

Or, for example, in the electrostatic protection transistor, the contact of the emitter thereof and the contact of the collector thereof may be arranged adjacent to each other.

This structure makes it easier for transient charge to flow into the electrostatic protection transistor.

Or, for example, the electrostatic protection transistor may be arranged adjacent to the output pad via which the output current from the output-stage transistor is fed out.

Or, for example, the electrostatic protection transistor may be arranged between the output pad via which the output current from the output-stage transistor is fed out and the region where the output-stage transistor is formed.

These structures help lower the impedance between the electrostatic protection transistor and the output pad, and thereby make it easier for transient charge to flow into the electrostatic protection transistor.

To achieve the above objects, according to still another aspect of the present invention, a method for fabricating a semiconductor device incorporating a regulator circuit including an output-stage transistor for supplying a current to an external circuit, the method includes: a first step of forming the output-stage transistor and an electrostatic protection transistor on a semiconductor substrate; and a second step of forming a diffusion resistor in the semiconductor device. Here, the electrostatic protection transistor is formed in parallel with the output-stage transistor. Moreover, the base impurity concentration of the electrostatic protection transistor is made lower than the base impurity concentration of the output-stage transistor. Furthermore, the base of the electrostatic protection transistor is formed by the second step.

This method for fabricating a semiconductor device allows the electrostatic protection transistor to operate faster without requiring an additional process.

As described above, regulator circuits and semiconductor devices according to the present invention offer enhanced resistance to static electricity.

### BRIEF DESCRIPTION OF THE DRAWINGS

FIG. 1 is a circuit diagram of the regulator system of a first embodiment of the present invention;

FIG. 2 is a diagram showing the cross-sectional structure of the output-stage transistor and the electrostatic protection transistors shown in FIG. 1;

FIG. 3 is a diagram showing the arrangement of the electrostatic protection transistor shown in FIG. 1 on the substrate;

FIG. 4 is a diagram showing the positional relationship between the output-stage transistor and the electrostatic protection transistor shown in FIG. 1 on the substrate;

FIG. 5 is a diagram showing another example of the cross-sectional structure of the output-stage transistor and the electrostatic protection transistor shown in FIG. 1;

FIG. 6 is a circuit diagram of the regulator system of a second embodiment of the present invention;

FIG. 7 is a circuit diagram of the regulator system of a third embodiment of the present invention;

FIG. 8 is a circuit diagram showing a modified example of the regulator system shown in FIG. 7;

FIG. 9 is an example of the circuit of a conventional regulator system; and

FIG. 10 is another example of the circuit of a conventional regulator system.

### DETAILED DESCRIPTION OF PREFERRED EMBODIMENTS

Hereinafter, embodiments of the present invention will be described specifically with reference to the accompanying drawings. Throughout the following description of the embodiments and in the drawings referred to in the course, such parts as are repeatedly mentioned and shown are identified with common reference numerals, and are to be understood to have the same features in structure, operation, etc. unless otherwise described; hence, no overlapping explanations of such parts will be given unless necessary.

### First Embodiment

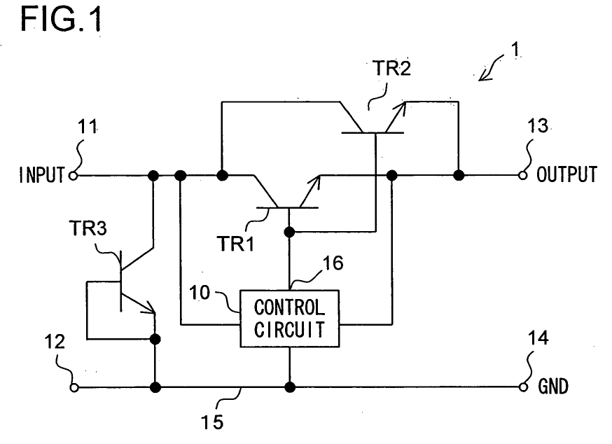

First, the regulator system (regulator circuit) of a first embodiment of the present invention will be described. FIG. 1 is a circuit diagram of the regulator system 1 of the first embodiment.

The regulator system 1 is composed of an output-stage transistor TR1, electrostatic protection transistors TR2 and TR3 that act as electrostatic failure protection elements, and a control circuit 10 that controls the output-stage transistor TR1. The output-stage transistor TR1 and the electrostatic protection transistors TR2 and TR3 are all NPN-type bipolar transistors.

The regulator system 1 has a pair of input terminals 11 and 12 and a pair of output terminals 13 and 14. An unillustrated direct-current voltage source is connected to the input terminals 11 and 12 so that a direct-current voltage from the direct-current voltage source is applied between the input terminals 11 and 12, with the input terminal 11 on the positive voltage side. An unillustrated external circuit is connected to the output terminals 13 and 14 so that the current and voltage needed by the external circuit are fed thereto via the output-stage transistor TR1.

The collector of the output-stage transistor TR1 is connected to the input terminal 11 and to the collectors of both the electrostatic protection transistors TR2 and TR3. The emitter of the output-stage transistor TR1 is connected to the output terminal 13 and to the emitter of the electrostatic protection transistor TR2. Thus, the electrostatic protection transistor TR2 is connected in parallel with the output-stage transistor TR1. The base of the output-stage transistor TR1 is connected to a control output terminal 16 of the control circuit 10 and to the base of the electrostatic protection transistor TR2.

The base and the emitter of the electrostatic protection transistor TR3 are connected together. The base and the emitter of the electrostatic protection transistor TR3 are then connected to the input terminal 12 on the negative voltage side and to a ground line 15 (GND), to which the output terminal 14 is connected. The ground line 15 acts as a reference potential point the potential at which is kept at a reference potential; for example, the ground line 15 is grounded.

For example, based on a voltage commensurate with (for example, obtained by dividing) the voltage at the output terminal 13, the control circuit 10 controls, via the control output terminal 16 thereof, the base voltage (base current level) of the output-stage transistor TR1 in such a way that the voltage at the output terminal 13 remains constant at a fixed voltage. The control circuit 10 operates by being driven with the voltage between the input terminals 11 and 12. The control circuit 10 also controls the emitter potential and the collector potential of the output-stage transistor TR1, and, for this purpose, control terminals of the control circuit 10 are connected respectively to the emitter and the collector of the output-stage transistor TR1.

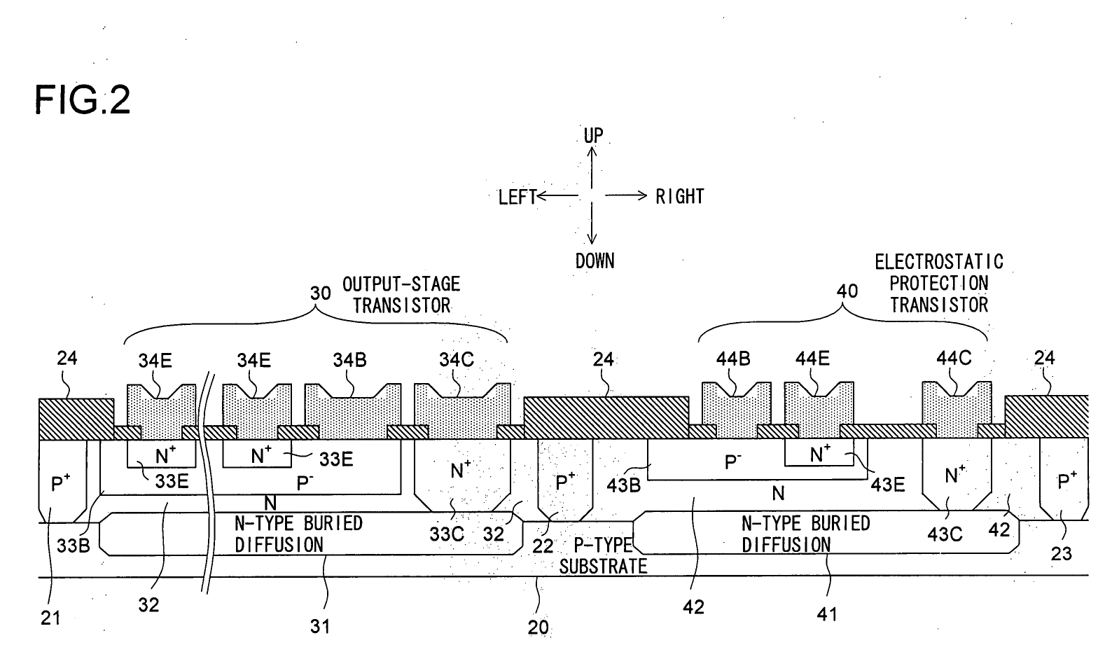

FIG. 2 is a diagram showing the cross-sectional structure of the output-stage transistor TR1 and the electrostatic protection transistors TR2 and TR3. The output-stage transistor TR1 and the electrostatic protection transistors TR2 and TR3 are formed on a single semiconductor substrate 20 (hereinafter abbreviated to “the substrate 20”). The substrate 20 is a P-type semiconductor substrate.

In FIG. 2, the output-stage transistor TR1 is shown as an output-stage transistor 30, and the electrostatic protection transistor TR2 is shown as an electrostatic protection transistor 40. Since the cross-sectional structure of the electrostatic protection transistor TR3 is similar to that of the electrostatic protection transistor 40 (TR2), it is omitted from illustration here. The control circuit 10 may also be formed on the substrate 20.

The output-stage transistor 30 is essentially composed of a base diffusion region 33B, an emitter diffusion region 33E, and a collector diffusion region 33C, and further includes an N-type buried diffusion layer 31 and an N-type epitaxial layer 32. The electrostatic protection transistor 40 is essentially composed of a base diffusion region 43B, an emitter diffusion region 43E, and a collector diffusion region 43C, and further includes an N-type buried diffusion layer 41 and an N-type epitaxial layer 42. In the following description, the base diffusion region 33B, the emitter diffusion region 33E, the collector diffusion region 33C, the base diffusion region 43B, the emitter diffusion region 43E, and the collector diffusion region 43C are also called simply “the regions 33B, 33E, 33C, 43B, 43E, and 43C” respectively.

The output-stage transistor 30 etc. are formed on the substrate 20 by epitaxial growth. The direction in which the thickness of the layer increases as epitaxial growth progresses is defined as the upward direction, and the opposite direction is defined as the downward direction (the direction toward the substrate). The output-stage transistor 30 is formed between element separation regions 21 and 22, and the electrostatic protection transistor 40 is formed between element separation regions 22 and 23. The direction running from the element separation region 22 located between the output-stage transistor 30 and the electrostatic protection transistor 40 to the element separation region 21 is defined as the leftward direction, and the direction running from the element separation region 22 to the element separation region 23 is defined as the rightward direction.

Now, the formation procedure and the cross-sectional structure of the output-stage transistor 30 etc. will be described. First, on the substrate 20, the N-type buried diffusion layer 31, which acts as the passage of the collector current of the output-stage transistor 30 and has a low resistance, and the N-type buried diffusion layer 41, which acts as the passage of the collector current of the electrostatic protection transistor 40 and has a low resistance, are formed by a diffusion process. Eventually, the right-hand end of the N-type buried diffusion layer 31 is located to the left of the element separation region 22, and the left-hand end of the N-type buried diffusion layer 31 is located to the right of the element separation region 21; the right-hand end of the N-type buried diffusion layer 41 is located to the left of the element separation region 23, and the left-hand end of the N-type buried diffusion layer 41 is located to the right of the element separation region 22.

After the diffusion process of the N-type buried layers 31 and 41, on the substrate 20 thus having the N-type buried layers 31 and 41 formed thereon, an N-type epitaxial layer is formed. Part of this epitaxial layer is formed into the base diffusion regions 33B and 43B, the emitter diffusion regions 33E and 43E, the collector diffusion regions 33C and 43C, and the element separation regions 21, 22, and 23 through the subsequent diffusion processes described below, and the rest of the epitaxial layer remains as the N-type epitaxial layers 32 and 42.

Next, by a separation diffusion process, a P-type impurity is diffused at a comparatively high concentration to form the P⁺ element separation regions (element separation diffusion regions) 21, 22, and 23. Subsequently, in a left-hand part of the epitaxial layer located between the element separation regions 21 and 22, a P-type impurity is diffused at a comparatively low concentration to form the P⁻ base diffusion region 33B, and, in a left-hand part of the epitaxial layer located between the element separation regions 22 and 23, a P-type impurity is diffused at a comparatively low concentration to form the P⁻ base diffusion region 43B.

Moreover, in a right-hand part of the epitaxial layer located between the element separation regions 21 and 22, an N-type impurity is diffused at a comparatively high concentration to form the N⁺ collector diffusion region 33C, and, in a right-hand part of the epitaxial layer located between the element separation regions 22 and 23, an N-type impurity is diffused at a comparatively high concentration to form the N⁺ collector diffusion region 43C. Furthermore, in regions within the base diffusion region 33B, an N-type impurity is diffused at a comparatively high concentration to form the N⁺ emitter diffusion region 33E on the base diffusion region 33B, and, in a region within the base diffusion region 43B, an N-type impurity is diffused at a comparatively high concentration to form the N⁺ emitter diffusion region 43E on the base diffusion region 43B. As shown in FIG. 2, the emitter diffusion region 33E is formed in a plurality of detached regions separate from each other in the left/right direction.

After these diffusion processes, over the top surfaces of the epitaxial layer and the individual regions, a field oxide film 24 is laid, which is an insulator. Then, parts of the field oxide film 24 are removed on the top surfaces of the regions 33B, 33E, 33C, 43B, 43E, and 43C. Then, through the holes (contact holes) thus formed by partial removal of the field oxide film 24 to secure electrical contact, electrodes 34B, 34E, 34C, 44B, 44E, and 44C of aluminum or the like are formed on the regions 33B, 33E, 33C, 43B, 43E, and 43C respectively.

The electrostatic protection transistor 40 is formed sufficiently smaller than the output-stage transistor 30. For example, the emitter area (emitter size) of the emitter diffusion region 43E in the electrostatic protection transistor 40 is made about one-tenth or less as large as the emitter area (emitter size) of the emitter diffusion region 33E in the output-stage transistor 30. This helps sufficiently reduce the influence of the electrostatic protection transistor on the output characteristics of the regulator system 1, and helps make the response of the electrostatic protection transistor faster. Thus, transient charge, which rises quickly, flows preferentially into the electrostatic protection transistor, and hence the output-stage transistor is effectively protected from the transient charge.

It should be noted that “the emitter area of the emitter diffusion region 33E” mentioned above denotes the total area of all the detached regions formed as the emitter diffusion region 33E in the output-stage transistor 30. It should also be noted that an emitter area denotes an area measured along the surface of the substrate 20.

Moreover, the spaces between the regions 43B, 43E, and 43C of the electrostatic protection transistor 40 and the element separation regions 22 and 23 are made sufficiently larger than the comparable spaces in the output-stage transistor 30 (for the sake of convenience, however, those spaces are not necessarily shown to be conspicuously so in FIG. 2).

More specifically, “the space (left/right-direction distance) S1 between the right-hand end of the base diffusion region 43B and the left-hand end of the collector diffusion region 43C” is made sufficiently larger than “the space (left/right-direction distance) S1′ between the right-hand end of the base diffusion region 33B and the left-hand end of the collector diffusion region 33C”.

Likewise, “the space S2a between the right-hand end of the emitter diffusion region 43E and the right-hand end of the base diffusion region 43B” is made sufficiently larger than “the space S2a′ between the right-hand end of the emitter diffusion region 33E (i.e. the right-hand end of the rightmost among the detached regions thereof) and the right-hand end of the base diffusion region 33B”, and (or) “the space S2b between the left-hand end of the emitter diffusion region 43E and the left-hand end of the base diffusion region 43B” is made sufficiently larger than “the space S2b′ between the left-hand end of the emitter diffusion region 33E (i.e. the left-hand end of the leftmost among the detached regions thereof) and the left-hand end of the base diffusion region 33B”.

Likewise, “the space S3 between the left-hand end of the base diffusion region 43B and the right-hand end of the element separation region 22” is made sufficiently larger than “the space S3′ between the left-hand end of the base diffusion region 33B and the right-hand end of the element separation region 21”. Likewise, “the space S4 between the right-hand end of the collector diffusion region 43C and the left-hand end of the element separation region 23” is made sufficiently larger than “the space S4′ between the right-hand end of the collector diffusion region 33C and the left-hand end of the element separation region 22”.

Securing sufficiently large distances between mutually adjacent junctions in this way helps enhance the resistance of the electrostatic protection transistor to junction breakdown, and thus helps enhance the resistance of the electrostatic protection transistor to transient charge (and hence it also helps enhance the resistance of the circuit as a whole to the transient charge). For example, against a given potential difference that may arise between the emitter and the base or between the emitter and collector, doubling the distance (space) between the junctions results in halving the electric field intensity appearing between the junctions, making junction breakdown less likely. Junction breakdown is particularly likely to occur where the junctions make contact with the field oxide film 24; by securing large left/right-direction distances between the junctions, however, it is possible to diminish the electric field strength and thereby achieve enhanced resistance to transient charge.

Incidentally, the spaces S2a and S2b are usually set equal, and the spaces S2a′ and S2b′ are usually set equal (for the sake of convenience, however, they are not shown to be conspicuously so in FIG. 2).

Moreover, the space S3 is made smaller than “the space between the right-hand end of the base diffusion region 43B and the left-hand end of the element separation region 23”, and in addition the space S3′ is made smaller than “the space between the right-hand end of the base diffusion region 33B and the left-hand end of the element separation region 22”. That is, the element separation region 22 is the element separation region closest to the base diffusion region 43B, and the element separation region 21 is the element separation region closest to the base diffusion region 33B.

Moreover, the space S4 is made smaller than “the space between the left-hand end of the collector diffusion region 43C and the right-hand end of the element separation region 22”, and in addition the space S4′ is made smaller than “the space between the left-hand end of the collector diffusion region 33C and the right-hand end of the element separation region 21”. That is, the element separation region 23 is the element separation region closest to the collector diffusion region 43C, and the element separation region 22 is the element separation region closest to the collector diffusion region 33C.

The injection amount for the base diffusion region 43B is lower than, for example about one-half of, the injection amount for the base diffusion region 33B of the output-stage transistor 30. That is, the impurity concentration in the base of the electrostatic protection transistor 40 is lower than, for example about one-half of, the impurity concentration in the base of the output-stage transistor 30. Thus, the base diffusion depth is smaller in the electrostatic protection transistor 40 than in the output-stage transistor 30, and the base width (the up/down-direction width of the base, i.e. its width in the direction of the thickness of the substrate) in the electrostatic protection transistor 40 is smaller than in the output-stage transistor 30. This shortens the time required by electrons to travel through the base, and thus helps make the operation of the electrostatic protection transistor 40 still faster. Moreover, punch-through is then more likely to occur, and thus the output-stage transistor is more effectively protected from transient charge.

The emitter diffusion regions 33E and 43E are formed, for example, by a single diffusion process and with equal impurity injection amounts. The base width depends on the width of the (P-type) base region that remains when the distribution of the N-type impurity formed by emitter diffusion and the distribution of the N-type impurity present in the N-type epitaxial layer are subtracted from the distribution of the P-type impurity formed by base diffusion. The lower the base impurity concentration, the larger the region that is eliminated (turned into the N-type) by emitter diffusion and by the epitaxial layer, and thus the smaller the eventual base width (of the P-type region).

In a case where one or more diffusion resistors are formed on the substrate 20 by a diffusion process, that diffusion process may be used to form the base diffusion region 43B of the electrostatic protection transistor 40. Specifically, at the same time that a P-type impurity is injected (diffused) in the process for forming one or more diffusion resistors, a P-type impurity is injected (diffused) also for the formation of the base diffusion region 43B. By sharing the process for forming one or more diffusion resistors with that for forming the base diffusion region 43B in this way, it is possible to make the operation of the electrostatic protection transistor faster without the need for an additional process.

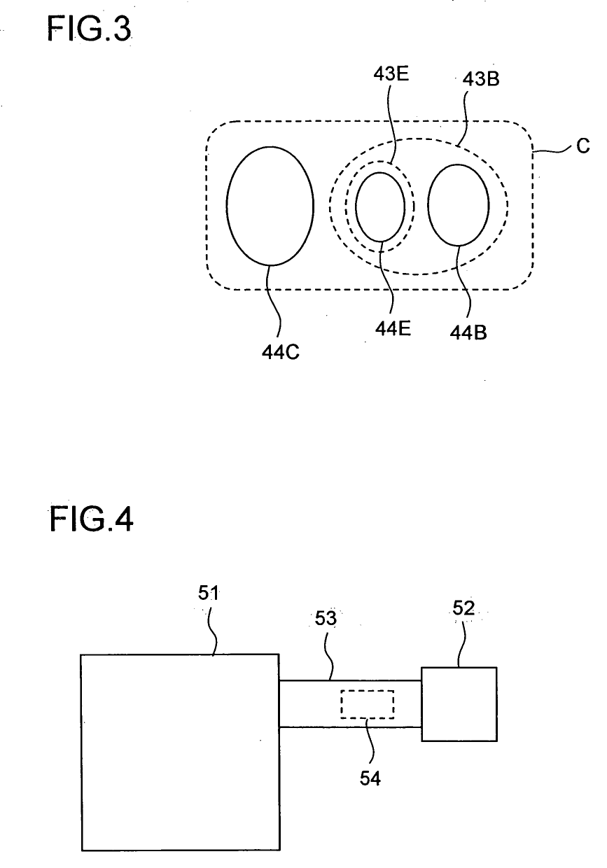

FIG. 3 is a diagram (layout diagram) showing the arrangement of the electrostatic protection transistor 40 on the substrate 20, as seen from above the substrate 20. The electrodes 44B, 44E, and 44C function respectively as a base contact for achieving electrical contact with the base diffusion region 43B, an emitter contact for achieving electrical contact with the emitter diffusion region 43E, and a collector contact for achieving electrical contact with the collector diffusion region 43C.

The N-type buried diffusion layer 41, the N-type epitaxial layer 42, and the collector diffusion region 43C together form the overall collector region C of the electrostatic protection transistor 40. In FIG. 3, the round-corner rectangular indicated by C shows the exterior shape of the overall collector region C (i.e. the border between the N-type epitaxial layer 42 and the element separation regions 22 and 23). Outside the collector region C lie the element separation regions (22 and 23).

As seen from above the substrate 20, the exterior shapes of the base diffusion region 43B, the emitter diffusion region 43E, and the collector region C each include a curve, and are each, for example, circular (though different from what is shown in FIG. 3, the collector region C may be given a circular exterior shape as seen from above the substrate 20). This, as compared with giving them rectangular exterior shapes, makes concentration of an electric field less likely, and thus enhances resistance to transient charge.

Moreover, as shown in FIG. 3, the emitter contact (electrode 44E) and the collector contact (electrode 44C) are arranged adjacent to each other. Specifically, for example, the electrodes 44C, 44E, and 44B are arranged in a lateral row (in the left/right direction) in the order named. Put another way, the distance between the center of the electrode 44E and the center of the electrode 44C is shorter than the distance between the center of the electrode 44B and the center of the electrode 44C.

Arranging the emitter contact and the collector contact adjacent to each other in this way shortens the distance over which transient charge needs to travel from the emitter contact to the collector contact (i.e. its travel distance through the N-type buried diffusion layer 41), and thus helps enhance the response to transient charge.

FIG. 4 is a diagram showing the arrangement of the output-stage transistor and the electrostatic protection transistor, as seen from above the substrate 20. In FIG. 4, reference numeral 51 represents the region where the output-stage transistor TR1, i.e. the output-stage transistor 30, is arranged, and reference numeral 54 represents the region where the electrostatic protection transistor TR2, i.e. the electrostatic protection transistor 40, is arranged. The electrostatic protection transistor TR3 may also be arranged in the region 54. Reference numeral 52 represents an output pad, and reference numeral 53 represents a conductor that connects the electrode 34E of the emitter of the output-stage transistor 30 to the output pad 52.

The output pad 52 corresponds to the output terminal 13 in the circuit diagram of FIG. 1, and, via the output pad 52, the output current from the output-stage transistor 30 (TR1) is fed out to an external circuit. The semiconductor integrated circuit inducing the output-stage transistor TR1 and the electrostatic protection transistors TR2 and TR3 is built in a multilayer conductor structure, having at least a first, lower, metal conductor layer and a second, upper, metal conductor layer laid on the substrate 20. The first, lower, metal conductor layer is assigned the electrodes (34E etc.) of the output-stage transistor 30 and the electrostatic protection transistor 40. The conductor 53 is laid as part of the second, upper, metal conductor layer.

As shown in FIG. 4, the region 54 where the electrostatic protection transistor 40 (TR2) is formed is arranged adjacent to the output pad 52. That is, as seen from above the substrate 20, no other element such as a transistor is arranged between the region 54 and the output pad 52. Moreover, as seen from above the substrate 20, the region 54 is arranged between the output pad 52 and the region 51.

The arrangement described above reduces the impedance (wiring capacitance and wiring resistance) between the electrostatic protection transistor 40 and the output pad 52, and thereby lets transient charge escape efficiently via the electrostatic protection transistor 40 (TR2) before flowing into the output-stage transistor 30 (TR1).

With a view to decreasing the impedance mentioned above, it is preferable that the region 54 be laid below the conductor 53 (closer than it to the substrate 20).

Usually, transient charge resulting from static electricity rises quickly. Hence, transient charge appearing at the output pad 52 (the output terminal 13) flows into the electrostatic protection transistor, which is smaller and thus operates faster, and thus the output-stage transistor is protected. Moreover, since the electrostatic protection transistor is so structured as to withstand transient charge with enhanced resistance, it is less prone to breakdown, and thus helps enhance the resistance of the circuit as a whole to static electricity.

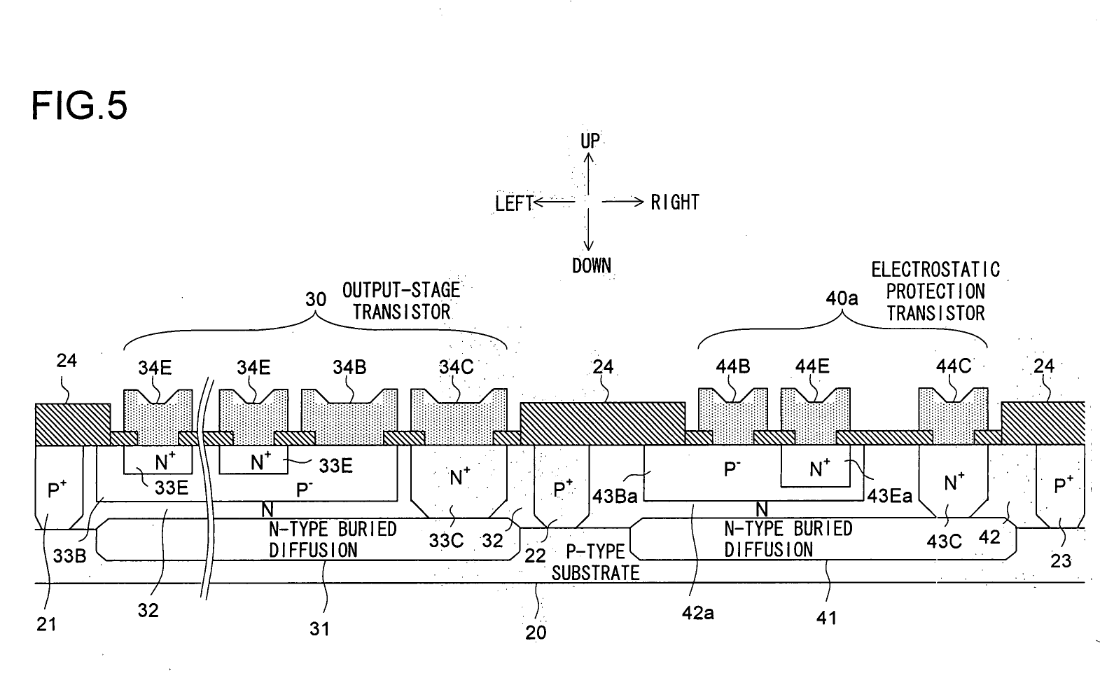

The cross-sectional structure of the electrostatic protection transistor may be modified as shown in FIG. 5. Specifically, the electrostatic protection transistor TR2 shown in FIG. 1 may be formed like the electrostatic protection transistor 40a shown in FIG. 5. Here, the electrostatic protection transistor TR3, too, may be so formed as to have a cross-sectional structure similar to that of the electrostatic protection transistor 40a. FIG. 5 is a diagram showing another example of the cross-sectional structure of the output-stage transistor and the electrostatic protection transistor. In FIG. 5, such parts as are shown also in FIG. 2 are identified with common reference numerals and symbols. When the cross-sectional structure shown in FIG. 5 is adopted, the output-stage transistor TR1 shown in FIG. 1 is formed invariably like the output-stage transistor 30. The cross-sectional structures shown in FIGS. 2 and 5 are similar, the differences being as described below.

The electrostatic protection transistor 40a is essentially composed of a base diffusion region 43Ba, an emitter diffusion region 43Ea, and a collector diffusion region 43C, and further includes an N-type buried diffusion layer 41 and an N-type epitaxial layer 42a. That is, here, the base diffusion region 43B, the emitter diffusion region 43E, and the N-type epitaxial layer 42 in the electrostatic protection transistor 40 are replaced respectively with the base diffusion region 43Ba, the emitter diffusion region 43Ea, and the N-type epitaxial layer 42a.

The left/right-direction structures of the base diffusion region 43Ba, the emitter diffusion region 43Ea, and the N-type epitaxial layer 42a are similar to those of the base diffusion region 43B, the emitter diffusion region 43E, and the N-type epitaxial layer 42. Thus, as described earlier with reference to FIG. 2, the distances between mutually adjacent junctions are longer than in the output-stage transistor.

The electrostatic protection transistor 40a is formed by a process similar to that used to form the electrostatic protection transistor 40 shown in FIG. 2, but here the injection amount for the base diffusion region 43Ba is equal to the injection amount for the base diffusion region 33B of the output-stage transistor 30. That is, the impurity concentration in the base of the electrostatic protection transistor 40a is equal to the impurity concentration in the base of the output-stage transistor 30 (hence the up/down-direction width (the width in the direction of the thickness of the substrate) of the remaining part of the N-type epitaxial layer 42a is smaller than that of the N-type epitaxial layer 42 shown in FIG. 2, and is equal to that of the N-type epitaxial layer 32).

Instead, the emitter of the electrostatic protection transistor 40a is formed deeper into the substrate than the emitter of the output-stage transistor 30. That is, the up/down-direction width (the width in the direction of the thickness of the substrate) of the emitter diffusion region 43Ea is greater than that of the emitter diffusion region 33E in the output-stage transistor 30. As a result, the base width (i.e. its up/down-direction width) in the electrostatic protection transistor 40a is smaller than that in the output-stage transistor 30. This shortens the time required for electrons to travel through the base, and thus helps make the operation of the electrostatic protection transistor faster. Moreover, punch-through is then more likely to occur, and thus the output-stage transistor is more effectively protected from transient charge.

Usually, emitter diffusion in NPN-type transistors is achieved by injection of arsenic (As); thus, the emitter diffusion region 33E of the output-stage transistor 30 is formed by injection of arsenic. By contrast, the emitter diffusion region 43Ea of the electrostatic protection transistor 40a is formed by injection of phosphorus (P), which has a higher diffusion coefficient than arsenic, so that the emitter is formed deeper.

In this embodiment, the output-stage transistor TR1 and the electrostatic protection transistors TR2 and TR3 are all built as NPN-type bipolar transistors. It is, however, also possible to use PNP-type bipolar transistors instead to achieve similar results. In a case where PNP-type bipolar transistors are used, the terms “N-type” and “P-type” in the description of the cross-sectional structure etc. have simply to be understood to read “P-type” and “N-type” respectively.

In FIG. 1, when the output terminal 13 is exposed to positive static electricity, the positive transient charge escapes to the ground line 15 by traveling via the emitter of the electrostatic protection transistor TR2, then the collector thereof, then the collector of the electrostatic protection transistor TR3, and then the emitter thereof in the order named. However, part of the transient charge may flow into the control circuit 10, causing electrostatic breakdown thereof. This drawback is improved in the second and third embodiments described below.

### Second Embodiment

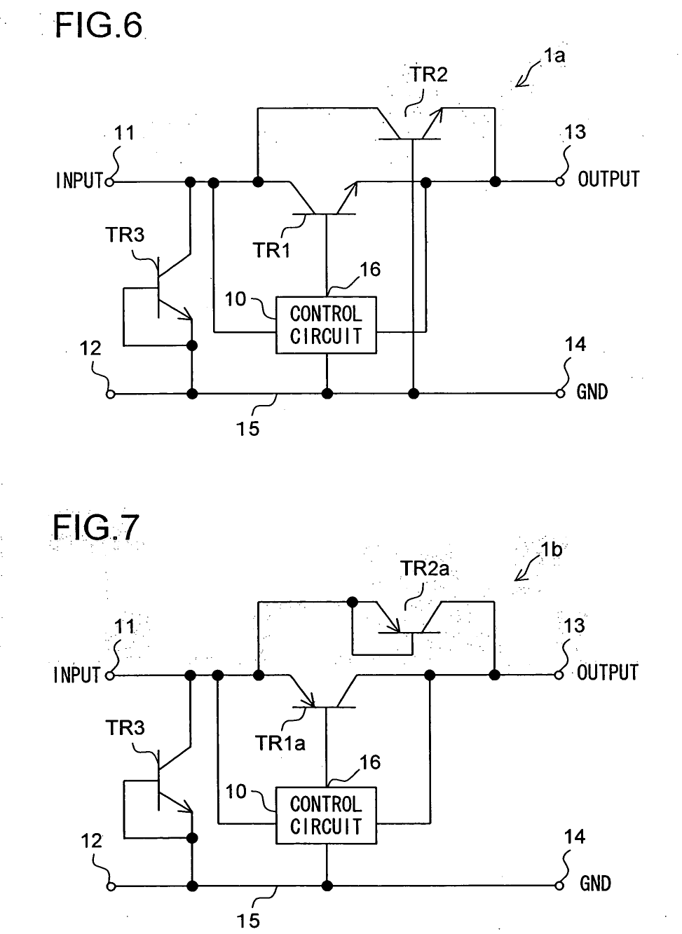

A second embodiment of the present invention will be described below. FIG. 6 is a circuit diagram of the regulator system 1a of a second embodiment of the present invention. The regulator system 1a differs from the regulator system 1 shown in FIG. 1 in that the base of the electrostatic protection transistor TR2 is connected not to the control output terminal 16 of the control circuit 10 but to the ground line 15; otherwise, the two regulator systems are similar.

Connecting the base of the electrostatic protection transistor TR2 to the ground line 15 makes it possible to prevent transient charge incoming via the output terminal 13 from flowing into the control circuit 10. In FIG. 6, a resistor (unillustrated) may be serially inserted between the base of the electrostatic protection transistor TR2 and the ground line 15; in other words, the base of the electrostatic protection transistor TR2 may be connected via a resistor to the ground line 15.

While no overlapping explanations will be given, it should be understood that the description of the output-stage transistor TR1 and the electrostatic protection transistors TR2 and TR3 given earlier in connection with the first embodiment with reference to the cross-sectional structure diagrams of FIGS. 2 and 5 and the arrangement diagrams of FIGS. 3 and 4 equally applies to the second embodiment. Thus, the second embodiment achieves results similar to those achieved by the first embodiment.

As in the first embodiment, in this embodiment also, the output-stage transistor TR1 and the electrostatic protection transistors TR2 and TR3 are all built as NPN-type bipolar transistors. It is, however, also possible to use PNP-type bipolar transistors instead. In a case where PNP-type bipolar transistors are used, the terms “N-type” and “P-type” in the description of the cross-sectional structure etc. have simply to be understood to read “P-type” and “N-type” respectively.

### Third Embodiment

A third embodiment of the present invention will be described below. FIG. 7 is a circuit diagram of the regulator system 1b of a third embodiment of the present invention.

The regulator system 1b is composed of an output-stage transistor TR1a, electrostatic protection transistors TR2a and TR3 that act as electrostatic failure protection elements, and a control circuit 10 that controls the output-stage transistor TR1a. The output-stage transistor TR1a and the electrostatic protection transistor TR2a are PNP-type bipolar transistors. That is, in the regulator system 1b, as compared with the regulator system 1 shown in FIG. 1, the output-stage transistor TR1 and the electrostatic protection transistor TR2 are replaced with the output-stage transistor TR1a and the electrostatic protection transistor TR2a, which are both of the PNP-type.

Like the regulator system 1 shown in FIG. 1, the regulator system 1b has a pair of input terminals 11 and 12 and a pair of output terminals 13 and 14. An unillustrated direct-current voltage source is connected to the input terminals 11 and 12 so that a direct-current voltage from the direct-current voltage source is applied between the input terminals 11 and 12, with the input terminal 11 on the positive voltage side. An unillustrated external circuit is connected to the output terminals 13 and 14 so that the current and voltage needed by the external circuit are fed thereto via the output-stage transistor TR1a.

The emitter of the output-stage transistor TR1a is connected to the input terminal 11, to the emitter of the electrostatic protection transistor TR2a, and to the collector of the electrostatic protection transistor TR3. The collector of the output-stage transistor TR1a is connected to the output terminal 13 and to the collector of the electrostatic protection transistor TR2a. Thus, the electrostatic protection transistor TR2a is connected in parallel with the output-stage transistor TR1a. The base of the output-stage transistor TR1a is connected to the control output terminal 16 of the control circuit 10, and the base and the emitter of the electrostatic protection transistor TR2a are connected together.

The base and the emitter of the electrostatic protection transistor TR3 are connected together. The base and the emitter of the electrostatic protection transistor TR3 are then connected to the input terminal 12 on the negative voltage side and to the ground line 15, to which the output terminal 14 is connected.

For example, based on a voltage commensurate with (for example, obtained by dividing) the voltage at the output terminal 13, the control circuit 10 controls, via the control output terminal 16 thereof, the base voltage (base current level) of the output-stage transistor TR1a in such a way that the voltage at the output terminal 13 remains constant at a fixed voltage. The control circuit 10 also controls the emitter potential and the collector potential of the output-stage transistor TR1a, and, for this purpose, control terminals of the control circuit 10 are connected respectively to the emitter and the collector of the output-stage transistor TR1a.

The cross-sectional structure of the output-stage transistor TR1a is similar to that of the output-stage transistor 30 shown in FIG. 2, and the cross-sectional structure of the electrostatic protection transistor TR2a is similar to that of the electrostatic protection transistor 40 (or 40a) shown in FIG. 2 (or FIG. 5). However, since the output-stage transistor TR1a and the electrostatic protection transistor TR2a are PNP-type bipolar transistors, the terms “N-type” and “P-type” in the cross-sectional structures shown in FIGS. 2 and 5 are to be understood to read “P-type” and “N-type” respectively.

It should be understood that the description of the output-stage transistor and the electrostatic protection transistors given earlier in connection with the first embodiment with reference to the cross-sectional structure diagrams of FIGS. 2 and 5 and the arrangement diagrams of FIGS. 3 and 4 equally applies to the third embodiment. Thus, the third embodiment achieves results similar to those achieved by the first embodiment.

Normally, the potential at the output terminal 13 is lower than the potential at the input terminal 11, and thus no current flows through the electrostatic protection transistor TR2a. When transient charge appears at the output terminal 13 and thus the potential at the output terminal 13 sharply rises, the electrostatic protection transistor TR2a operates faster than the output-stage transistor TR1a, and hence the transient charge preferentially flows through the electrostatic protection transistor TR2a. Thus, the output-stage transistor TR1a is effectively protected from electrostatic breakdown.

In FIG. 7, a resistor (unillustrated) may be serially inserted between the base and the emitter of the electrostatic protection transistor TR2a; in other words, the base of the electrostatic protection transistor TR2 may be connected to its own emitter via a resistor.

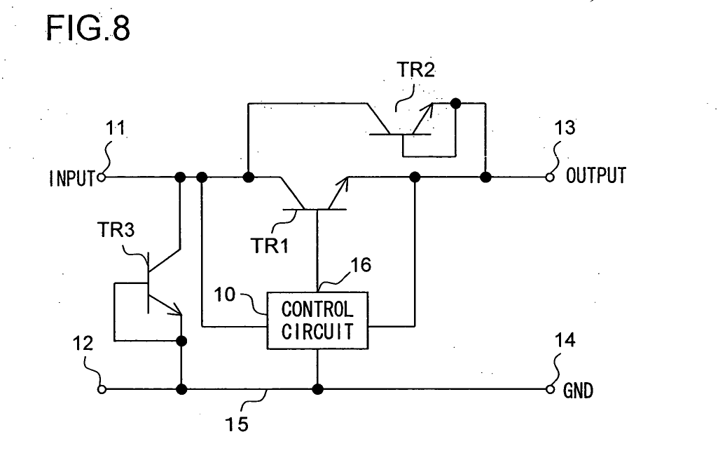

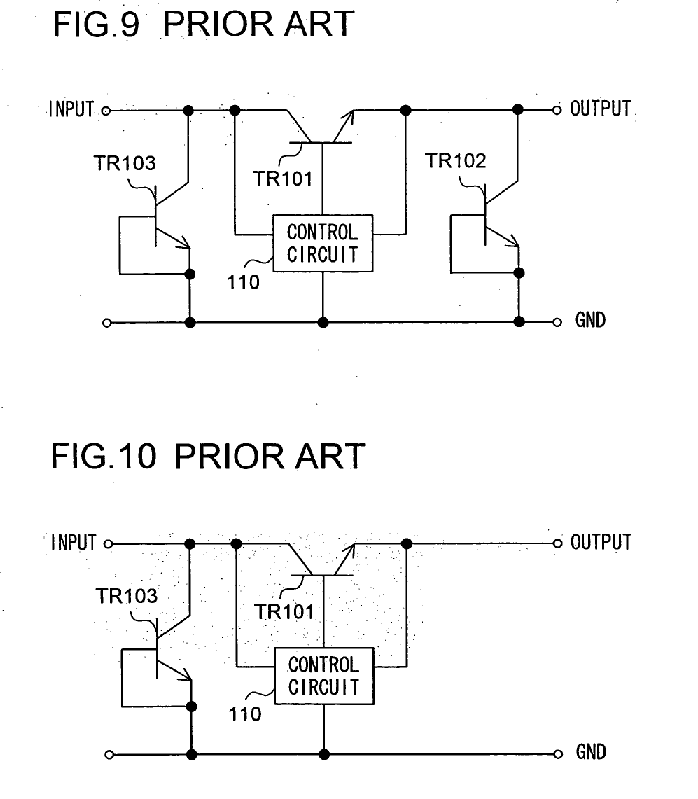

In this embodiment, the output-stage transistor TR1a and the electrostatic protection transistor TR2a are built as PNP-type bipolar transistors. It is, however, also possible to use NPN-type bipolar transistors instead as an output-stage transistor TR1 and a electrostatic protection transistor TR2 as shown in FIG. 8. The electrostatic protection transistor TR3 may be built as a PNP-type bipolar transistor.

The first to third embodiments may be freely combined so long as no contradiction arises; that is, a feature in one embodiment (for example, a feature in the first embodiment) may be applied in any other embodiment (for example, the second embodiment) unless doing so creates a contradiction.

What is claimed is:

1. A regulator circuit including an output-stage transistor for supplying a current to an external circuit,
wherein an electrostatic protection transistor is formed in parallel with the output-stage transistor.

2. The regulator circuit according to claim 1,
wherein an emitter, a base, and a collector of the electrostatic protection transistor are connected respectively to an emitter, a base, and a collector of the output-stage transistor.

3. The regulator circuit according to claim 1,
wherein an emitter and a collector of the electrostatic protection transistor are connected respectively to an emitter and a collector of the output-stage transistor, and
wherein a base of the electrostatic protection transistor is connected to a reference potential point.

4. The regulator circuit according to claim 1,
wherein an emitter and a collector of the electrostatic protection transistor are connected respectively to an emitter and a collector of the output-stage transistor, and
wherein a base and the emitter of the electrostatic protection transistor are connected together.

5. A semiconductor device incorporating a regulator circuit including an output-stage transistor for supplying a current to an external circuit,
wherein the output-stage transistor and an electrostatic protection transistor are formed on a semiconductor substrate, and
wherein the electrostatic protection transistor is formed in parallel with the output-stage transistor.

6. The semiconductor device according to claim 5,
wherein an emitter area of the electrostatic protection transistor is smaller than an emitter area of the output-stage transistor.

7. The semiconductor device according to claim 6,
wherein the emitter area of the electrostatic protection transistor is equal to or smaller than one-tenth of the emitter area of the output-stage transistor.

8. The semiconductor device according to claim 5,
wherein the output-stage transistor and the electrostatic protection transistor are formed on the semiconductor substrate while being separated by an element separation region, and
wherein a space between a base and a collector of the electrostatic protection transistor, a space between an emitter and the base of the electrostatic protection transistor, a space between the base of the electrostatic protection transistor and part of the element separation region closest thereto, and a space between the collector of the electrostatic protection transistor and part of the element separation region closest thereto are larger respectively than comparable spaces in the output-stage transistor.

9. The semiconductor device according to claim 5,
wherein a base impurity concentration of the electrostatic protection transistor is lower than a base impurity concentration of the output-stage transistor.

10. The semiconductor device according to claim 5,
wherein an emitter of the electrostatic protection transistor is formed deeper than an emitter of the output-stage transistor.

11. The semiconductor device according to claim 5,
wherein, as seen from above the semiconductor substrate, an emitter, a base, and a collector of the electrostatic protection transistor are each given an exterior shape including a curve.

12. The semiconductor device according to claim 11,
wherein the exterior shape of each of the emitter, the base, and the collector of the electrostatic protection transistor is circular.

13. The semiconductor device according to claim 5,
wherein, in the electrostatic protection transistor, a contact of an emitter thereof and a contact of a collector thereof are adjacent to each other.

14. The semiconductor device according to claim 5,
wherein the electrostatic protection transistor is arranged adjacent to an output pad via which an output current from the output-stage transistor is fed out.

15. The semiconductor device according to claim 5,
wherein the electrostatic protection transistor is arranged between an output pad via which an output current from the output-stage transistor is fed out and a region where the output-stage transistor is formed.

16. A method for fabricating a semiconductor device incorporating a regulator circuit including an output-stage transistor for supplying a current to an external circuit, the method comprising:
a first step of forming the output-stage transistor and an electrostatic protection transistor on a semiconductor substrate, and
a second step of forming a diffusion resistor in the semiconductor device,
wherein the electrostatic protection transistor is formed in parallel with the output-stage transistor,
wherein a base impurity concentration of the electrostatic protection transistor is made lower than a base impurity concentration of the output-stage transistor, and
wherein a base of the electrostatic protection transistor is formed by the second step.
